(19) United States
(12) Patent Application Publication
(10) Pub. No.: US 2026/0178089 A1
(43) Pub. Date: Jun. 25, 2026

(54) POWER CONVERSION APPARATUS, SYSTEM CARD, MANUFACTURING METHOD FOR AN INTEGRATED CAPACITOR SUBSTRATE AND POWER SUPPLY MODULE

(71) Applicant: MetaPWR Electronics Co., Ltd., Shanghai (CN)

(72) Inventors: Da Jin, Shanghai (CN); Yahong Xiong, Shanghai (CN)

(73) Assignee: MetaPWR Electronics Co., Ltd., Shanghai (CN)

(21) Appl. No.: 19/430,307

(22) Filed: Dec. 23, 2025

(30) Foreign Application Priority Data
Dec. 23, 2024 (CN) 202411900848.X
Jan. 26, 2025 (CN) 202510121953.1

(51) Int. Cl. G06F 1/18; H02M 1/00; H02M 3/00; H02M 3/335; H05K 3/00; H05K 3/46

(52) U.S. Cl. CPC G06F 1/189; H02M 1/0048; H02M 3/003; H02M 3/33592; H05K 3/0038; H05K 3/4623; H05K 3/4652; H05K 2201/10015; H05K 2201/10734

(57) ABSTRACT

A power conversion apparatus including a full-bridge circuit, two magnetic cores, and four synchronous rectification circuits is provided. The full-bridge circuit comprises two upper switches, two middle switches, a resonant capacitor, a first high-voltage winding and a second high-voltage winding; each of the synchronous rectification circuits comprises a first lower switch, a second lower switch, a first low-voltage winding and a second low-voltage winding; and further comprising an input terminal and an output terminal, wherein the input terminal comprises an input positive terminal and a GND terminal, and the output terminal comprises an output positive terminal and a GND terminal.

### CROSS-REFERENCE TO RELATED APPLICATION

This application claims the priority benefit of China application serial no. 202411900848.X filed on Dec. 23, 2024, and China application serial no. 202510121953.1 filed on Jan. 26, 2025. The entirety of the above-mentioned patent application is hereby incorporated by reference herein and made a part of this specification.

### BACKGROUND

### Description of Related Art

With the development of artificial intelligence, the power requirements of intelligent data processing chips, such as GPU/CPU/NPU/TPU, etc. (collectively, xPU) are increasingly high, so that the power of the server is increased, the input voltage of the server gradually changes from 12V to 48V, and the operating voltage of the xPU is decreasing as the process progresses, and gradually moves from 0.8 V to 0.65 V. Therefore, the ratio of the input voltage to the output voltage becomes larger and larger, so that the two-stage buck circuit architecture gradually becomes the mainstream; the two-stage buck circuit architecture comprises a front-stage converter and a post-stage voltage regulator. In order to reduce the size of the post-stage voltage regulator, to improve the dynamic response speed of the post-stage voltage regulator, the switching frequency of the voltage regulator is increased from 1 MHz to 10 MHz, so that the input voltage of the post-stage voltage regulator is getting lower and lower, which is from 12V to 6.75V, it is further possible to reduce to 5V or 3.3V. In this way, the voltage ratio (hereinafter referred to as the voltage gain ratio) of the input voltage to the output voltage of the front-stage converter becomes larger and larger; in addition, with the lower output voltage of the front-stage converter and higher output power, the output current of the front-stage converter is increased.

The present application provides a front-stage converter with a high voltage gain ratio. The ratio of the input voltage to the output voltage can reach 15:1, and provides a suitable voltage and power for the post-stage voltage regulator, so that the post-stage voltage regulator can work in the optimal state. Further, by optimizing the winding manner of the transformer winding and the arrangement of the power device, the low loss and small volume characteristics of the front-stage converter are realized. The present application further provides a power supply structure using the present front-stage converter, and further reduces parasitic losses on the output current path of the front-stage converter.

### SUMMARY

In view of the above, one of the objectives of the application is to provide a power conversion apparatus, comprising a full-bridge circuit, two magnetic cores, and four synchronous rectification circuits, wherein the full-bridge circuit comprises two upper switches, two middle switches, a resonant capacitor, a first high-voltage winding and a second high-voltage winding; the resonant capacitor, the first high-voltage winding and the second high-voltage winding are electrically connected in series; the four synchronous rectification circuits are electrically connected in parallel, and each synchronous rectification circuit comprises a first lower switch, a second lower switch, a first low-voltage winding and a second low-voltage winding; the low-voltage windings in the same synchronous rectification circuit are wound on the same magnetic core;
the first high-voltage winding and the second high-voltage winding are wound around two magnetic cores;
further comprising an input terminal and an output terminal; the input terminal includes an input positive terminal and a GND terminal, the output terminal includes an output positive terminal and a GND terminal; the full bridge circuit is electrically connected to the input terminal, and the four synchronous rectification circuits are electrically connected to the output terminal.

Preferably, the four synchronous rectification circuits are a first synchronous rectification circuit, a second synchronous rectification circuit, a third synchronous rectification circuit, and a fourth synchronous rectification circuit, respectively; in each synchronous rectification circuit, a second end of the first low-voltage winding and a second end of the second low-voltage winding are electrically connected to the output positive terminal, a first end of the first low-voltage winding is electrically connected to the first lower switch, and a first end of the second low-voltage winding is electrically connected to the second lower switch; and the first lower switch and the second lower switch are both electrically connected to the GND terminal.

Preferably, the two upper switches are a first upper switch and a second upper switch; the two middle switches are a first middle switch and a second middle switch; the first upper switch and the first middle switch are electrically connected to a first node, and the second upper switch and the second middle switch are electrically connected to a second node; the resonant capacitor and the first high-voltage winding and the second high-voltage winding are connected in series between the first node and the second node; a first end of the second high-voltage winding is electrically connected to a second end of the first high-voltage winding; the first upper switch and the second upper switch are both electrically connected to the input positive terminal, and both the first middle switch and the second middle switch are electrically connected to the output positive terminal.

Preferably, the first end of the first high-voltage winding and the first end of the second high-voltage winding, the first end of each of the first low-voltage windings and the second end of each of the second low-voltage windings are with the same polarity.

Preferably, the two magnetic cores are a first magnetic core and a second magnetic core, respectively; each magnetic core comprises a first side column, a middle column, a second side column, an upper magnetic cover and a lower magnetic cover; the first side column, the second side column and the middle column are located between the upper magnetic cover and the lower magnetic cover; the first side column, the middle column, and the second side column are sequentially arranged in the same direction; a first winding channel is between the first side column and the middle column, and a second winding channel is between the second side column and the middle column; each magnetic core comprises an inner side surface and an outer side surface opposite to each other, and the inner side surface of the first magnetic core is adjacent to the inner side surface of the second magnetic core.

Preferably, the first low-voltage winding in each synchronous rectification circuit passes through one winding channel, and the second low-voltage winding in each synchronous rectification circuit passes through another winding channel.

Preferably, the first end of the first high-voltage winding and the second end of the second high-voltage winding are both disposed adjacent to the inner side surface of the magnetic core, and are arranged adjacent to the first winding channels; from the first end of the first high-voltage winding to the second end of the second high-voltage winding, first the high-voltage winding is wound at least three circles around the middle column of the first magnetic core and the middle column of the second magnetic core in one direction, reaching an intermediate node, then divided into a first winding and a second winding, the first winding is wound one circle around the middle column of the first magnetic core in the same direction to reach the second node, the second winding is wound one circle around the middle column of the second magnetic core to reach the second node; the first winding and the second winding being electrically connected in parallel between the intermediate node and the second node, and the second node being the second end of the second high-voltage winding.

Preferably, the power conversion apparatus, further comprising a substrate, wherein the substrate comprises a top surface and a bottom surface opposite to each other, and the two magnetic cores are respectively assembled with the substrate; the lower switches in the first synchronous rectification circuit are disposed adjacent to the inner side surface of the first magnetic core, the first lower switch of the first synchronous rectification circuit is disposed adjacent to the first winding channel, and the second lower switch of the first synchronous rectification circuit is disposed adjacent to the second winding channel; the lower switches in the second synchronous rectification circuit are disposed adjacent to the outer side surface of the first magnetic core, the first lower switch of the second synchronous rectification circuit is disposed adjacent to the second winding channel, and the second lower switch of the second synchronous rectification circuit is disposed adjacent to the first winding channel; the lower switches in the third synchronous rectification circuit are disposed adjacent to the inner side surface of the second magnetic core, and the first lower switch of the third synchronous rectification circuit is disposed adjacent to the second winding channel, and the second lower switch of the third synchronous rectification circuit is disposed adjacent to the first winding channel; the lower switches in the fourth synchronous rectification circuit are disposed adjacent to the outer side surface of the second magnetic core, and the first lower switch of the fourth synchronous rectification circuit is disposed adjacent to the first winding channel, and the second lower switch of the fourth synchronous rectification circuit is disposed adjacent to the second winding channel.

Preferably, the first low-voltage winding in the first synchronous rectification circuit passes through the first winding channel of the first magnetic core in a first direction from the first end to the second end, and the second low-voltage winding in the first synchronous rectification circuit passes through the second winding channel of the first magnetic core in the first direction from the first end to the second end; the first low-voltage winding in the second synchronous rectification circuit passes through the second winding channel of the first magnetic core in a second direction from the first end to the second end, and the second low-voltage winding in the second synchronous rectification circuit passes through the first winding channel of the first magnetic core in the second direction from the first end to the second end; the first low-voltage winding in the third synchronous rectification circuit passes through the second winding channel of the second magnetic core in the second direction from the first end to the second end, and the second low-voltage winding in the third synchronous rectification circuit passes through the first winding channel of the second magnetic core in the second direction from the first end to the second end; the first low-voltage winding in the fourth synchronous rectification circuit passes through the first winding channel of the second magnetic core in the first direction from the first end to the second end, the second low-voltage winding in the fourth synchronous rectification circuit passes through the second winding channel of the second magnetic core in the first direction from the first end to the second end, and the first direction is opposite to the second direction.

Preferably, the power conversion apparatus, further comprising at least three output capacitor groups, wherein the at least three output capacitor groups are respectively arranged on the outer side of the lower switches of the second synchronous rectification circuit, between the lower switches of the first synchronous rectification circuit and the lower switches of the third synchronous rectification circuit, and on the outer side of the lower switches of the fourth synchronous rectification circuit.

Preferably, the power conversion apparatus, further comprising at least four groups of output terminals, each group of output terminals being disposed adjacent to the lower switch of a corresponding synchronous rectification circuit.

Preferably, the first lower switch comprises two switches connected in parallel, the second lower switch comprises two switches connected in parallel, the first lower switch, the second lower switch, and the output capacitor are all arranged on the top surface and the bottom surface of the substrate; two switches connected in parallel in the first lower switch are respectively arranged on the top surface and the bottom surface of the substrate, projections of the two parallel switches on the top surface of the substrate at least partially overlap; two switches in parallel in the second lower switch are respectively provided with the top surface and the bottom surface of the substrate, and projections of the two parallel switches on the top surface of the substrate at least partially overlap; the projections of the output capacitor arranged on the top surface and the bottom surface of the substrate on the top surface of the substrate at least partially overlap.

Preferably, the two first winding channels are arranged in a penetrating manner in a horizontal direction, and the two second winding channels are arranged in a penetrating manner in a horizontal direction.

Preferably, the power conversion apparatus, further comprising a substrate, wherein the substrate comprises a top surface and a bottom surface opposite to each other, and the two magnetic cores are respectively assembled with the substrate; the two upper switches and the two middle switches are disposed adjacent to the first side column, and the two upper switches and the two middle switches are sequentially arranged in the same direction along a sequence of the first middle switch, the first upper switch, the second upper switch, and the second middle switch; the resonant capacitor is disposed adjacent to the upper switch and the middle switch.

Preferably, the power conversion apparatus, further comprising an input terminal and an input capacitor, wherein the input terminal and the input capacitor are disposed adjacent to the upper switch and middle switch.

Preferably, the power conversion apparatus, further comprising a substrate, the substrate comprising a top surface and a bottom surface opposite to each other, a plurality of holes and a plurality of hole grooves, the holes and the hole grooves both penetrating the top surface and the bottom surface of the substrate, the holes being used for placing the first side column and the middle column of the magnetic core, and the hole grooves being used for placing the second side column of the magnetic core.

A power conversion apparatus, comprising an input positive terminal, an input negative terminal, an output positive terminal, an output negative terminal, a high-voltage switch, a low-voltage switch, and a magnetic assembly, wherein the magnetic assembly comprises two magnetic cores, a high-voltage winding and a low-voltage winding; the high-voltage switch is electrically connected to the high-voltage winding, and the low-voltage switch is electrically connected to the low-voltage winding; the two magnetic cores are respectively a first magnetic core and a second magnetic core; each magnetic core comprise an upper magnetic cover, a lower magnetic cover, a first side column, a middle column, and a second side column; the first side column, the middle column, and the second side column are sequentially arranged in the same direction; the first side column, the middle column, and the second side column are all arranged between the upper magnetic cover and the lower magnetic cover; in the same magnetic core, a first winding channel is between the first side column and the middle column, and a second winding channel is between the second side column and the middle column; the first magnetic core and the second magnetic core are arranged adjacent to each other, the two first winding channels are arranged in a penetrating manner in a horizontal direction, and the two second winding channels are arranged in a penetrating manner in the horizontal direction; the high winding wound the middle columns of the two magnetic cores; the low-voltage winding penetrates the first winding channel or the second winding channel.

Preferably, the high-voltage winding comprises a first high-voltage winding and a second high-voltage winding; a second end of the first high-voltage winding is connected in series with a first end of the second high-voltage winding, and a first end of the first high-voltage winding and a second end of the second high-voltage winding are both located between the two magnetic cores and are arranged adjacent to the first side column; the winding manner of the high-voltage winding from the first end to the second end is: first, starting from between the two magnetic cores to wind simultaneously around two middle columns in the same direction for N circles and then reach an intermediate node, wherein N is a natural number greater than or equal to 1, and the intermediate node is also located in the middle of the two magnetic cores; then dividing from the intermediate node into a first winding and a second winding, the first winding continues to be wound around the middle column of the first magnetic core in the same direction for one circle and then reaches a second node, the second winding continues to be wound around the middle column of the second magnetic core in the same direction for one circle and then reaches the second node, the first winding and the second winding are connected in parallel between the intermediate node and the second node, and the second node is the second end of the second high-voltage winding.

Preferably, the low-voltage switch is respectively located on two opposite sides of the first magnetic core and two opposite sides of the second magnetic core, a first end of the low-voltage winding is electrically connected to the low-voltage switch, a second end of the low-voltage winding is electrically connected to the output positive terminal, the low-voltage switch is electrically connected to the output negative terminal, and the low-voltage winding comprises a first low-voltage winding and a second low-voltage winding; the first low-voltage winding and the second low-voltage winding pass through the first winding channel and the second winding channel in the same magnetic core, respectively.

A system card, comprising a system board, a load chip, a socket, a voltage regulator array, and the power conversion apparatus, wherein the system board comprises a top surface and a bottom surface opposite to each other, the load chip is arranged on the top surface of the system board, and the voltage regulator array is arranged on the bottom surface of the system board; projections of the voltage regulator array and the load chip on the system board are at least partially overlapped, the voltage regulator array are electrically connected with the load chip by means of the system board, and the power conversion apparatus is electrically connected to the voltage regulator array; the sockets are disposed on two opposite sides of the voltage regulator array, and the sockets are electrically connected to the load chip.

Preferably, the system card, further comprising a module substrate; the module substrate comprises a top surface and a bottom surface opposite to each other wherein the voltage regulator array and the power conversion apparatus are both disposed on the top surface of the module substrate, and the power conversion apparatuses are disposed on two opposite sides of the voltage regulator array;
the bottom surface of the module substrate is provided with a BGA pad, and the bottom surface of the module substrate is welded to the bottom surface of the system board through the BGA pad.

Preferably, the power conversion apparatus is disposed on the top surface of the system board and disposed adjacent to two opposite sides of the load chip, and a wiring direction between the power conversion apparatus and the voltage regulator array is along X direction; a wiring direction between the load chip and the socket is along the Y direction.

Preferably, the system card, further comprising a first output capacitor and a second output capacitor, wherein the first output capacitor is disposed adjacent to the power conversion apparatus, and the first output capacitor is electrically connected to the output terminal of the power conversion apparatus; the second output capacitor is disposed around each voltage regulator in the voltage regulator array, and the second output capacitor is electrically connected to an output terminal of the voltage regulator array.

Preferably, the system card, further comprising a module substrate, the module substrate comprises a top surface and a bottom surface opposite to each other; wherein the voltage regulator array is disposed on the top surface of the module substrate, the bottom surface of the module substrate is provided with a BGA pin, and the module substrate is electrically connected to the system board by means of the BGA pin; a second output capacitor is integrated in the module substrate, and the second output capacitor is electrically connected to an output terminal of the voltage regulator array.

A manufacturing method for an integrated capacitor substrate, comprising a capacitor and a double-sided board, wherein the capacitor is with two pads; the manufacturing method comprising:
Step 1: embedding the capacitor in the double-sided substrate, and drawing pad pins of the capacitor by means of laser drilling;
Step 2: respectively laminating an insulating layer and a layer of copper foil on a top surface and a bottom surface of the double-sided board with the embedded capacitor, thereby forming at least four layers of the substrate;
Step 3: for the at least four-layer substrate, a via is provided in a region where the capacitor is not embedded; in a region where the capacitor is embedded, a laser hole is drilled at a position corresponding to the pads lead-out position; the capacitor is disposed adjacent to the via.
Step 4: a BGA pin is formed in a position of the via in the at least four-layer substrate and the position of the laser hole.

Preferably, the capacitor is a silicon capacitor, and a pad of the silicon capacitor is a square pad.

A power supply module, comprising a circuit substrate, a voltage regulator array and a plurality of power conversion apparatuses; the circuit substrate comprises a top surface and a bottom surface opposite to each other; the voltage regulator array and the power conversion apparatuses are disposed on the bottom surface of the circuit substrate; the power conversion apparatuses are electronically connected with the voltage regulator array, and supply power to the voltage regulator array; the voltage regulator array supplies power to a load chip; the projections of the load chip and the voltage regulator array on the bottom surface of the circuit substrate are at least partially overlapped; the plurality of the power conversion apparatuses are disposed on the two opposite sides of the voltage regulator array respectively.

Preferably, the circuit substrate is a system board, and the load chip is disposed on a top surface of the system board.

Preferably, a BGA pin is disposed on the top surface of the circuit substrate.

Compared with the prior art, the application has the following beneficial effects:

In the present application, a high-voltage gain ratio of 15:1 of a power conversion apparatus is realized by means of a winding manner of windings and a magnetic core of two groups of magnetic assemblies.

By means of the two groups of magnetic assemblies, the four groups of synchronous rectification circuits, and the four groups of output terminals, and the arrangement of the corresponding devices, reducing the parasitic resistance of the large current path, and improving the conversion efficiency of the power conversion apparatus.

A power supply structure using the present front-stage converter is also provided, which reduces the parasitic loss on the output current path of the front-stage converter.

### BRIEF DESCRIPTION OF THE DRAWINGS

FIG. 1 is a schematic circuit diagram of a power conversion apparatus.

FIG. 2A to FIG. 2B are winding manners of a winding.

FIG. 3A to FIG. 3C are schematic layout diagrams of a power conversion apparatus.

FIG. 4A to FIG. 4D are an arrangement of the power conversion apparatus on a system board.

FIG. 5A and FIG. 5B are another arrangement of the power conversion apparatus on a system board.

FIG. 6A and FIG. 6B are schematic diagrams of an output capacitor embedded module substrate.

### DESCRIPTION OF THE EMBODIMENTS

One of the cores of the present application is to provide a power conversion device with a high ratio of an input voltage to an output voltage, which is also called a power conversion apparatus with a high voltage gain ratio, or a proportional conversion apparatus with a high voltage gain ratio.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

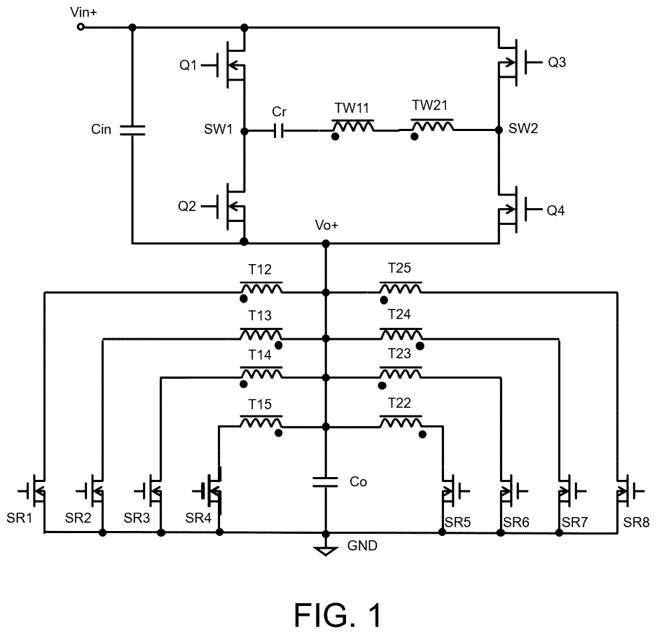

The present application provides a front-stage converter by taking a proportional converter with a voltage gain ratio of 15:1 as an example. The circuit diagram is shown in FIG. 1, and comprises a first sub-circuit, a second sub-circuit, a first high-voltage winding, a second high-voltage winding, a resonant capacitor, an input capacitor, an output capacitor, an input terminal and an output terminal. The input terminal comprises an input positive terminal and an input negative terminal, and the output terminal comprises an output positive terminal and an output negative terminal. In the present embodiment, the input negative terminal and the output negative terminal are electrically connected to a GND terminal. The first sub-circuit comprises an upper switch Q1, a middle switch Q2, a first synchronous rectification circuit and a second synchronous rectification circuit. The second sub-circuit comprises an upper switch Q3, a middle switch Q4, a first synchronous rectification circuit and a second synchronous rectification circuit. A source electrode of the upper switch Q1 in the first sub-circuit and a drain electrode of the middle switch Q2 in the first sub-circuit are electrically connected to a first node SW1, a drain electrode of the upper switch Q1 is electrically connected to the input positive terminal Vin+, and a source electrode of the middle switch Q2 is electrically connected to the output positive terminal Vo+; a source electrode of the upper switch Q3 in the second sub-circuit and a drain electrode of the middle switch Q4 are electrically connected to a second node SW2, a drain electrode of the upper switch Q3 is electrically connected to the input positive terminal Vin+, and a source electrode of the middle switch Q4 is electrically connected to the output positive terminal Vo+. The resonant capacitor Cr, the first high-voltage winding TW11 and the second high-voltage winding TW21 are electrically connected in series, and are connected across the first node SW1 and the second node SW2; wherein a second end of the first high-voltage winding TW11 is electrically connected to a first end of the second high-voltage winding TW21.

The first synchronous rectification circuit in the first sub-circuit comprises a first low-voltage winding T12, a second low-voltage winding T15, a first lower switch SR1, and a second lower switch SR4; a second end of the first low-voltage winding T12 and a second end of the second low-voltage winding T15 are both electrically connected to the output positive terminal Vo+, a first end of the first low-voltage winding T12 is electrically connected to a drain of the first lower switch SR1, a first end of the second low-voltage winding T15 is electrically connected to a drain of the second lower switch SR4, and sources of the first lower switch SR1 and the second lower switch SR4 are both electrically connected to the GND terminal. The second synchronous rectification circuit in the first sub-circuit comprises a first low-voltage winding T14, a second low-voltage winding T13, a first lower switch SR3 and a second lower switch SR2; a second end of the first low voltage winding T14 and a second end of the second low voltage winding T13 are both electrically connected to the output positive terminal Vo+; a first end of the first low voltage winding T14 is electrically connected to a drain of the first lower switch SR3, a first end of the second low voltage winding T13 is electrically connected to a drain of the second lower switch SR2, and sources of the first lower switch SR3 and the second lower switch SR2 are both electrically connected to the GND terminal. The first synchronous rectification circuit in the second sub-circuit comprises a first low-voltage winding T22, a second low-voltage winding T25, a first lower switch SR5 and a second lower switch SR8; a second end of the first low-voltage winding T22 and a second end of the second low-voltage winding T25 are both electrically connected to the output positive terminal Vo+; a first end of the first low-voltage winding T22 is electrically connected to a drain of the first lower switch SR5, a first end of the second low-voltage winding T25 is electrically connected to a drain of the second lower switch SR8, and sources of the first lower switch SR5 and the second lower switch SR8 are both electrically connected to the GND terminal. The second synchronous rectification circuit in the second sub-circuit comprises a first low-voltage winding T24, a second low-voltage winding T23, a first lower switch SR7 and a second lower switch SR6; a second end of the first low-voltage winding T24 and a second end of the second low-voltage winding T23 are both electrically connected to an output positive terminal Vo+; a first end of the first low-voltage winding T24 is electrically connected to a drain of the first lower switch SR7, a first end of the second low-voltage winding T23 is electrically connected to a drain of the second lower switch SR6, and sources of the first lower switch SR7 and the second lower switch SR6 are both electrically connected to the GND terminal. In the present embodiment, four synchronous rectification circuits are connected in parallel, thereby the parasitic resistance on the output circuit are greatly reduced and the loss of the power conversion apparatus is reduced.

In addition, the input capacitor Cin is connected between the input positive terminal Vin+and the output positive terminal Vo+, and the output capacitor Co is connected across the output positive terminal Vo+and the GND terminal. The first end of each high-voltage winding, the first end of each first low-voltage winding, and the second end of each second low-voltage winding have the same polarity, and are labeled as point ends; and the high-voltage winding and the low-voltage winding shown in this embodiment are wound on the two magnetic cores.

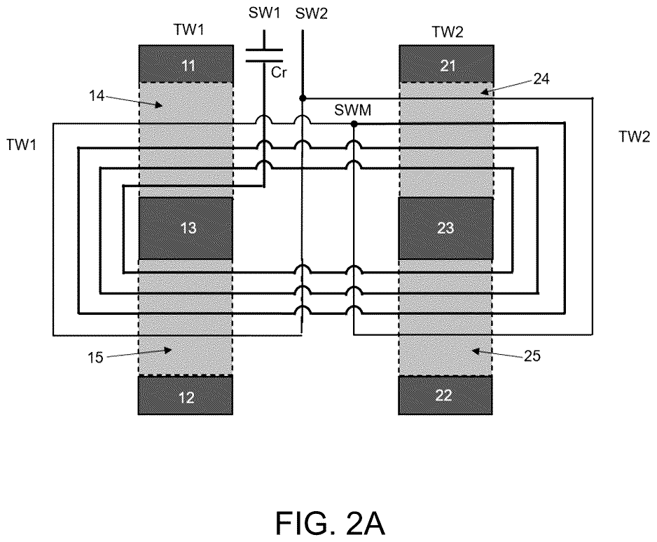

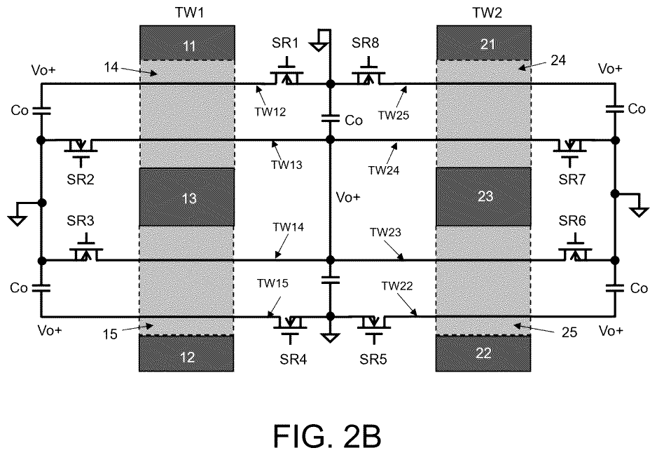

As shown in FIG. 2A and FIG. 2B, the winding manner of the high-voltage winding is shown in FIG. 2A, and the winding manner of the low-voltage winding is shown in FIG. 2B. The present embodiment comprises two magnetic cores, which are magnetic cores TW1 and TW2, respectively. The magnetic core TW1 comprises a first side column 11, a second side column 12, a middle column 13, an upper magnetic cover and a lower magnetic cover; the first side column 11, the second side column 23 and the middle column 13 are located between the upper magnetic cover and the lower magnetic cover; the first side column 11, the middle column 13, and the second side column 12 are sequentially arranged in the same direction; a channel between the first side column 11 and the middle column 13 is a first winding channel 14, and a channel between the middle column 13 and the second side column 12 is a second winding channel 15. The magnetic core TW2 comprises a first side column 21, a second side column 22, a middle column 23, an upper magnetic cover and a lower magnetic cover; the first side column 21, the second side column 22 and the middle column 23 are located between the upper magnetic cover and the lower magnetic cover; the first side column 21, the middle column 23 and the second side column 22 are sequentially arranged in a same direction. A channel between the first side column 21 and the middle column 23 is a first winding channel 24; a channel between the middle column 23 and the second side column 22 is a second winding channel 25. Each magnetic core further comprises an inner side surface and an outer side surface opposite to each other; the inner side surface of the magnetic core TW1 is disposed adjacent to the inner side surface of the magnetic core TW2; the first winding channels of the two magnetic cores penetrate in a horizontal direction, and the second winding channels penetrate in a horizontal direction.

As shown in FIG. 2A, the first end of the first high voltage winding TW11 (electrically connected to one end of the resonant inductor Cr) and the second end of the second high voltage winding TW21 (the second node SW2) are both disposed between the two magnetic cores, and are disposed adjacent to the first side columns 11 and 21. The winding manner of the first end of the first high-voltage winding TW11 to the second end of the second high-voltage winding TW21 is as follows: firstly, from the first end of the first high-voltage winding TW11, passed through the first winding channel 14 from the inner side surface of the magnetic core, then wound three circles around the middle column 13 and the middle column 23 in a counterclockwise direction, reached an intermediate node SWM, and then divided into a first winding and a second winding; the first winding is wound one circle around the middle column 13 in a counterclockwise direction to reach the second node SW2; the second winding is wound one circle around the middle column 23 in a counterclockwise direction to reach the second node SW2, and the first winding and the second winding are connected in parallel. In the present embodiment, the first high-voltage winding TW11 and the second high-voltage winding TW21 are connected in parallel with one circle to achieve 0.5 turns of each high-voltage winding, and then the first high-voltage winding TW11 and the second high-voltage winding TW21 are connected in series with three turns to achieve the winding of 3.5 turns of each high-voltage winding. In other embodiments, 0.5 turns of each high-voltage winding can also be implemented in the same way, and then N turns in series are connected in series to achieve the winding of the (N +0.5) turns of each high-voltage winding, where N is a natural number.

As shown in FIG. 2B, each low-voltage winding passes through a corresponding winding channel once, that is, each low-voltage winding is 0.5 turns. According to the expression of the output voltage in this embodiment: Vo=(Vin−Vo)* D *0.5/3.5, the duty cycle D=0.5, so the voltage gain ratio Vin/Vo=15.

In detail, in each sub-circuit, the first ends of the low-voltage windings in the first synchronous rectification circuit are arranged adjacent to the inner side surface of the magnetic core, and the second ends of the low-voltage windings are arranged close to the outer side surface of the corresponding magnetic core; the first ends of the low-voltage windings in the second synchronous rectification circuit are arranged adjacent to the outer side surface of the corresponding magnetic core, and the second ends of the low-voltage windings are arranged adjacent to the inner side surface of the magnetic core. Correspondingly, in the first synchronous rectification circuit of the first sub-circuit, the first low-voltage winding TW12 passes through the first winding channel 14 from the first end to the second end in a second direction (from right to left), and the second low-voltage winding TW15 passes through the second winding channel 15 from the first end to the second end in the second direction (from right to left); In the second synchronous rectification circuit of the first sub-circuit, the first low voltage winding TW14 passes from the first end to the second end through the second winding channel 15 in a first direction (from left to right), and the second low voltage winding TW13 passes from the first end to the second end through the first winding channel 14 in the first direction (from left to right). In the first synchronous rectification circuit of the second sub-circuit, the first low-voltage winding TW22 passes through the second winding channel 25 from the first end to the second end in the first direction, and the second low-voltage winding TW25 passes through the first winding channel 24 from the first end to the second end in the first direction; in the second synchronous rectification circuit of the second sub-circuit, the first low-voltage winding TW24 passes through the first winding channel 24 from the first end to the second end in the second direction, and the second low-voltage winding TW23 passes through the second winding channel 25 from the first end to the second end in the second direction.

Referring to FIG. 1 to FIG. 2B, the upper switch and the middle switch in the first sub-circuit, the upper switch and the middle switch in the second sub-circuit, the first high-voltage winding, the second high-voltage winding and the resonant capacitor form a full-bridge circuit; according to the winding manner of the high-voltage winding and the low-voltage winding as described above, a high-voltage gain ratio is achieved; and the full-bridge circuit drives the two transformers and the four groups of synchronous rectification circuits. On the one hand, the parasitic resistance of the large current path is reduced, and the loss of the power conversion apparatus is reduced; on the other hand, the thickness of the magnetic core is further reduced.

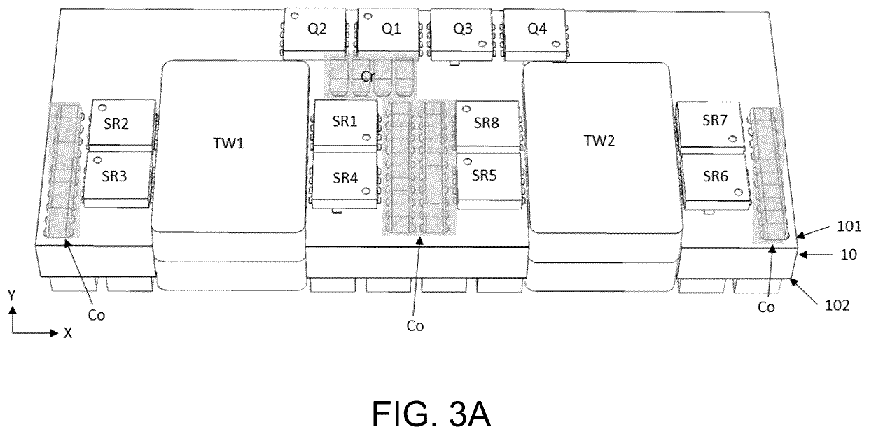

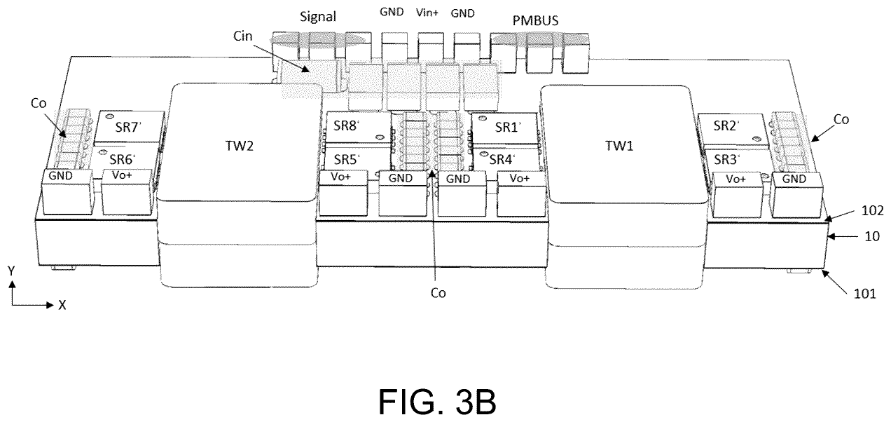

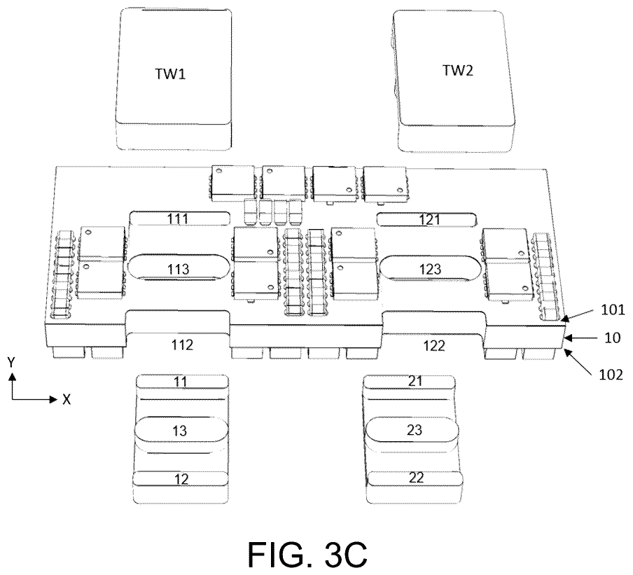

FIG. 3A is a schematic top view of the power conversion apparatus, FIG. 3B is a schematic diagram of a bottom surface of the power conversion apparatus, and FIG. 3C is a top exploded view. The power conversion apparatus comprises a substrate 10, wherein the substrate 10 comprises an upper surface 101, a lower surface 102, holes 111, 113, 121 and 123 and hole grooves 112 and 122; the holes 111, 113, 121 and 123 and the hole grooves 112 and 122 penetrate through the upper surface 101 and the lower surface 102 respectively for the magnetic columns to pass through. After the magnetic cores TW1 and TW2 are assembled on the substrate 10, the two magnetic cores are arranged along the X-axis direction, and each winding channel is parallel to the X-axis.

In the present embodiment, in the first sub-circuit, the lower switch SR1 and SR4 in the first synchronous rectification circuit are arranged adjacent to the inner side surface of the magnetic core TW1, and the first lower switch SR1 is arranged adjacent to the first winding channel 14, and the second lower switch SR4 is arranged adjacent to the second winding channel 15; the lower switches SR2 and SR3 in the second synchronous rectification circuit are disposed adjacent to the outer side surface of the magnetic core TW1, and the first lower switch SR3 is disposed adjacent to the second winding channel 15, and the second lower switch SR2 is disposed adjacent to the first winding channel 14. In the second sub-circuit, the lower switch SR5 and the SR8 in the first synchronous rectification circuit are arranged adjacent to the inner side surface of the magnetic core TW2, and the first lower switch SR5 is arranged adjacent to the second winding channel 25, and the second lower switch SR8 is arranged adjacent to the first winding channel 24; the lower switches SR7 and SR6 in the second synchronous rectification circuit are disposed adjacent to the outer side surface of the magnetic core TW2, and the first lower switch SR7 is disposed adjacent to the first winding channel 24, and the second lower switch SR6 is disposed adjacent to the second winding channel 25. In the present embodiment, each of the first lower switch and the second lower switch is implemented by two switches connected in parallel, the lower switches are respectively arranged on the upper surface 101 and the lower surface 102, and each lower switch arranged on the upper surface 101 and the lower switch arranged on the lower surface 102 are connected in parallel in a one-to-one correspondence, and the one-to-one correspondence is that the projections of the device arranged on the upper surface and the corresponding device arranged on the lower surface on the upper surface of the substrate at least partially overlap.

The output capacitors Co are divided into three groups, which are respectively arranged between the lower switches SR1/SR4, and the lower switches SR5/SR8, and on the outer sides of the lower switches SR2 and SR3, and on the outer sides of the lower switches SR6 and SR7. In the present embodiment, the output capacitors Co are simultaneously arranged on the upper surface 101 and the lower surface 102, and the positions of the output capacitor groups arranged on the upper surface and the positions of the corresponding output capacitor groups arranged on the lower surface are in one-to-one correspondence. On the upper surface 101 and/or the lower surface 102, along the X-axis direction, the lower switch SR2/SR3, the magnetic core TW1, the lower switch SR1/SR4, the lower switch SR5/SR8, the magnetic core TW2 and the lower switch SR7/SR6 are arranged in sequence. Furthermore, the output capacitor, the lower switch SR2/SR3, the magnetic core TW1, the lower switch SR1/SR4, the output capacitor, the lower switch SR5/SR8, the magnetic core TW2, the lower switch SR7/SR6, and the output capacitor are arranged in sequence.

On the lower surface 102 of the substrate, an input terminal and an output terminal are also provided, the input terminal comprising an input positive terminal Vin+ and a GND terminal, the output terminal comprising an output positive terminal Vo+ and a GND terminal. In the present embodiment, the power conversion apparatus comprises four groups of output terminals and a group of input terminals, the four groups of output terminals are respectively arranged on the inner side surface and the outer side surface of each magnetic core, and are respectively arranged adjacent to the second side column of the magnetic core and the corresponding lower switch; in each group of output terminals, each output positive terminal is arranged adjacent to the magnetic core with respect to the GND terminal; preferably, each output positive terminal Vo+and GND terminal are arranged in a line along the X-axis. In the present embodiment, there is a center line between the magnetic cores TW1 and TW2, and the center line extends along the Y-axis direction; the magnetic cores TW1 and TW2 are symmetrical along the center line, and the settings of the lower switch and the groups of output capacitors are also symmetrical along the center line. Furthermore, the output terminals are also symmetrical along the center line.

In addition, on the upper surface 101 of the substrate, the upper switch and the middle switch in the first sub-circuit and the second sub-circuit are disposed adjacent to the first side column of the magnetic core, and are symmetrically disposed on both sides of the center line. The four switches are arranged in an order from left to right according to the middle switch in the first sub-circuit, the upper switch in the first sub-circuit, the upper switch in the second sub-circuit, and the middle switch in the second sub-circuit. The drain of the upper switch Q1 and the drain of the upper switch Q3 are disposed adjacently and electrically connected; the source of the upper switch Q1 is disposed adjacent to and electrically connected to the drain of the middle switch Q2; and the source of the upper switch Q3 is disposed adjacent to and electrically connected to the drain of the middle switch Q4. The resonant capacitor is disposed between the upper/middle switch and the lower switch. The input terminal, a signal terminal, and a PM Bus terminal are further disposed on the lower surface 102 of the substrate, and the input terminal is disposed adjacent to the center line and disposed on two sides of the center line; and the input capacitor Cin is disposed between the input terminal and the lower switch and adjacent to the upper/middle switch.

In the present embodiment, through the two groups of magnetic assemblies, the four paralleled groups of synchronous rectification circuit and the four groups of output terminals, the parasitic resistance of the large current path greatly reduced and the loss of the power conversion apparatus is reduced too. Furthermore, by arranging the lower switch in parallel on the upper surface and the lower surface of the substrate, the loss caused by the parasitic resistance is further reduced.

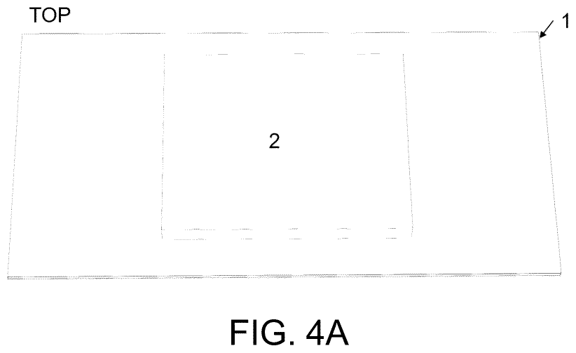

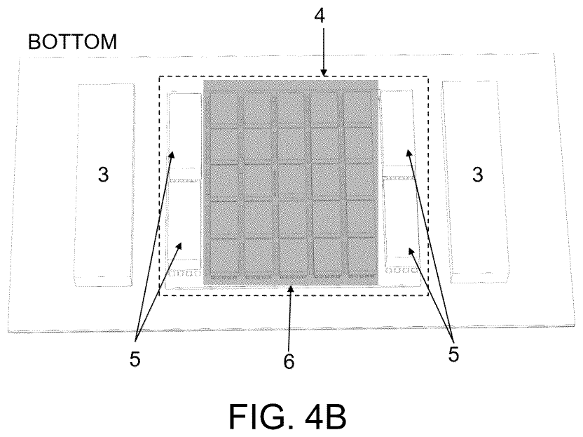

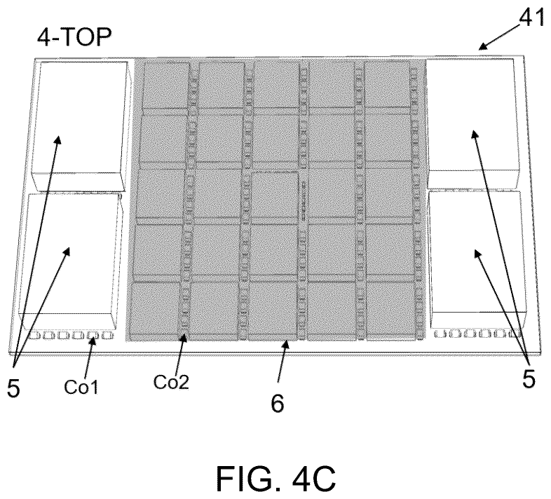

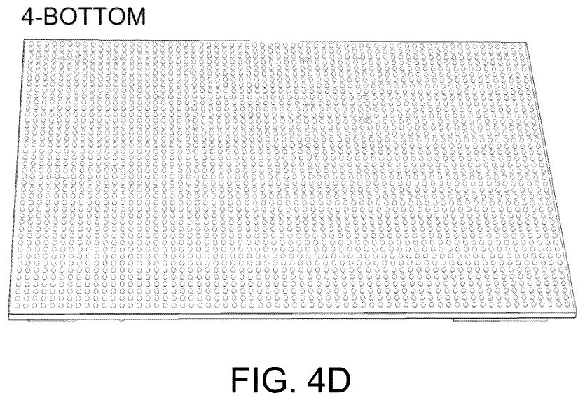

An application structure of the disclosed power conversion apparatus on a system card (for example, a GPU card) is shown in FIG. 4A to FIG. 4D. The system card comprises a system board 1, xPU 2, Socket 3, and a power supply module 4, wherein the xPU 2 is arranged on a top surface of the system board 1, the Socket 3 and the power supply module 4 are arranged on a bottom surface of the system board 1, and the two Socket 3 are respectively arranged on two opposite sides of the power supply module 4.

The power supply module 4 is configured to convert a voltage of 54 V to a voltage of 0.8 V and supply power to the xPU. As shown in FIG. 4C and FIG. 4D, the power supply module 4 comprises a module substrate 41, a proportional conversion apparatus 5, a voltage regulator array 6 and a BGA pin; both the proportional conversion apparatus 5 and the voltage regulator array 6 are provided on a top surface of the module substrate 41; and the BGA pins are provided on a bottom surface of the module substrate 41. In the present embodiment, there are four proportional conversion apparatus 5, which are respectively arranged on two opposite sides of the voltage regulator array 6, and two proportional conversion apparatus 5 are provided at each side. There are 25 voltage regulators, arranged in an array of 5×5, and input ends of the 25 voltage regulators are connected in parallel and output ends thereof are connected in parallel. The power supply module 4 further comprises output capacitors Co1 and Co2, the output capacitor Co1 is the output capacitor of the proportional conversion apparatus, and the output capacitors Co1 are arranged around the proportional conversion device 5. The output capacitor Co2 is an output capacitor of the voltage regulator, and the output capacitors Co2 are arranged around each voltage regulator.

In detail, the proportional conversion apparatus is used to realize the conversion of the input voltage 50V to the output voltage 3.3V, and the voltage regulator implements the conversion of the input voltage 3.3V to the output voltage 0.8V. In the present embodiment, the ratio of the input voltage to the output voltage of the proportional conversion apparatus is 15:1, the lower the output voltage, the higher switching frequency used in the voltage regulator is facilitated, the inductance of the output inductor and the volume of the voltage regulator are reduced, and better dynamic response performance can be obtained. However, the lower the output voltage of the proportional conversion apparatus, in order to obtain the same output power, the larger the output current of the proportional conversion apparatus, the greater the loss in the current path between the proportional conversion apparatus and the voltage regulator. Therefore, in the power supply module 4, the proportional conversion apparatus and the voltage regulator are arranged on the same module substrate, so that there is only the parasitic resistance loss caused by the wiring on the module substrate between the proportional conversion device and the voltage regulator, without the parasitic loss caused by the BGA pin solder joint, thereby further improving the conversion efficiency of the power supply module. In addition, the voltage regulator array 6 is arranged in the middle of the power supply module 4, so that the output end of each voltage regulator is connected to the BGA pin by the shortest distance, and then is connected to a input end pin of the xPU by the shortest distance. In other words, the voltage regulator, the BGA pin of the output of the power supply module, the BGA pin of the input of the xPU and the xPU are directly opposite in position in the vertical direction, so that the parasitic resistance between the voltage regulator and the xPU is further reduced. On the other hand, the proportional conversion apparatus is disposed on both sides of the voltage regulator array, so that the proportional conversion apparatus is relatively far from the xPU, which does not affect the configuration of the BGA pin of the input of the xPU.

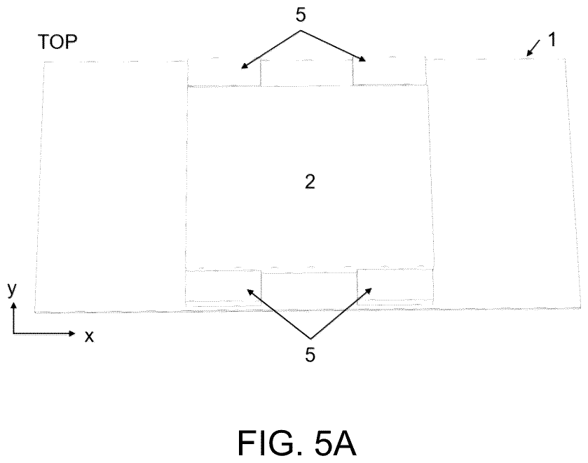

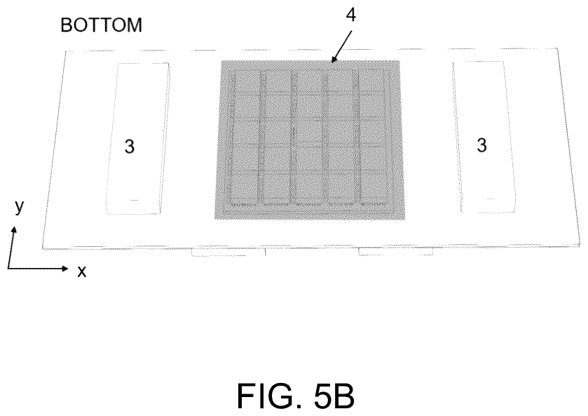

FIG. 5A and FIG. 5B disclose another embodiment, both the xPU 2 and the proportional conversion apparatus 5 are disposed on a top surface of the system board 1, and the proportional conversion apparatus 5 is disposed on an upper side and a lower side of the xPU, respectively; the voltage regulator array 6 and the Socket 3 are arranged on the bottom surface of the system board 1; the position of the voltage regulator array 6 and the position of the xPU are directly opposite to each other, that is, located directly below the xPU, and the two Socket 3 are respectively arranged on the left side and the right side of the voltage regulator array 6. In the present embodiment, the power supply module only comprises the voltage regulator array 6, the size of the power supply module is reduced, and the reliability of the power supply system can be further improved. The wiring between the xPU and the Socket is arranged in the X direction, and the wiring between the proportional conversion apparatus and the power supply module is arranged in the Y direction. Therefore, the above two wirings do not interfere with each other on the system board, and the parasitic resistance between the proportional conversion device and the power supply module can be reduced as much as possible, which is benefit to reduce the loss on the parasitic resistance.

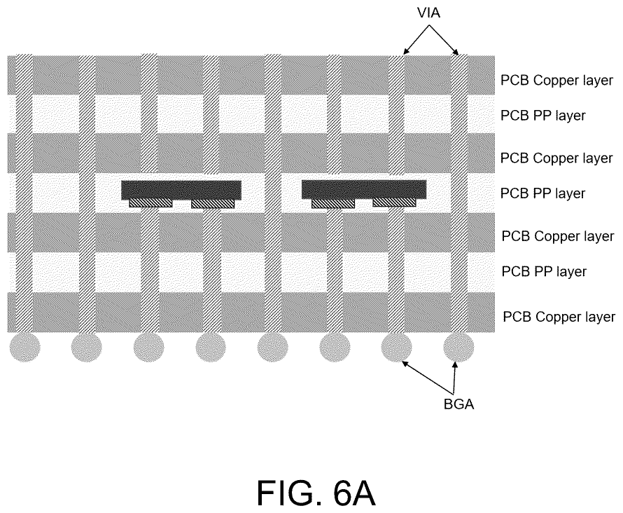

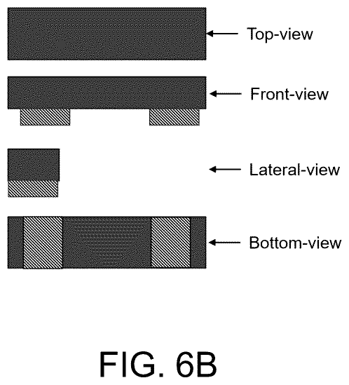

In the module substrate, the output capacitor Co2 of the voltage regulator may be further integrated, and the output capacitor Co2 herein adopts a silicon capacitor with a square pad, as shown in FIG. 6A to FIG. 6B, wherein FIG. 6B shows a top-view, a front-view, a lateral-view, and a bottom-view of the silicon capacitor, and FIG. 6A shows a schematic side view of the silicon capacitor embedded in the module substrate. In the present embodiment, a module substrate having at least four layers is used as an example for description. The specific method comprises: first embedding a silicon capacitor into a double-sided board, and extracting a square copper pad of the silicon capacitor by means of laser drilling; and then respectively laminating a layer pp and a layer of copper foil on the top surface and the bottom surface of the double-sided board with the embedded silicon capacitor, thereby forming a module substrate having at least four layers. For the at least four-layer module substrate, a via is provided in a region where no silicon capacitor is embedded; in the region where the silicon capacitor is embedded, a laser hole is provided at the square copper pad; finally, the position of the via in the at least four-layer module substrate and the position of the silicon capacitor laser hole are implanted to form a BGA pin of the power supply module; each silicon capacitor is placed adjacent to the via penetrating through the at least four-layer module substrate; there may be at least two copper layers, or at least one layer pp layer, between the silicon capacitor and the BGA pin, and the internal resistance between the BGA pins of the same electrical network can be reduced, so that the current flowing through each BGA pin is close to each other, thereby reducing the current density of the BGA pin; the silicon capacitor is placed adjacent to the via, so that the current of each BGA pin is close to each other. The output capacitor is embedded in the module substrate, which can further increase the capacity of the output capacitor of the voltage regulator, and further improve the dynamic response characteristics of the power supply module.

The power supply module 4 in the above two embodiments is not limited to the proportional conversion apparatus to convert a 50V input voltage into a 3.3V output voltage, and the voltage regulator converts a 3.3V input voltage into a 0.8V output voltage; the voltage regulator converts a 48V input voltage into a 12V output voltage, and the voltage regulator converts the 12V input voltage into an output voltage of 0.8V. In other embodiments, the proportional conversion apparatus and the voltage regulator may also adopt other input voltages and output voltages, and the structure layout shown in the foregoing embodiments may be used. Moreover, the technical features of the proportional conversion apparatus described above can also be applied to an adjustable conversion apparatus, the same technical effects can be achieved.

The switch disclosed by the application can be used for realizing the functions of the switch disclosed by the application, such as a Si MOSFET,SiC MOSFET,GaN MOSFET or IGBT MOSFET.

The power supply module according to the embodiment can be an independent module or a part of the electronic device, and can meet the technical features and advantages disclosed by the application.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A power conversion apparatus, comprising:
a full-bridge circuit, two magnetic cores, and four synchronous rectification circuits,
wherein the full-bridge circuit comprises two upper switches, two middle switches, a resonant capacitor, a first high-voltage winding and a second high-voltage winding; the resonant capacitor, the first high-voltage winding and the second high-voltage winding are electrically connected in series; the four synchronous rectification circuits are electrically connected in parallel, and each synchronous rectification circuit comprises a first lower switch, a second lower switch, a first low-voltage winding and a second low-voltage winding; the low-voltage windings in the same synchronous rectification circuit are wound on the same magnetic core;
wherein the first high-voltage winding and the second high-voltage winding are wound around two magnetic cores;
wherein the power conversion apparatus further comprises an input terminal and an output terminal; the input terminal includes an input positive terminal and a GND terminal, the output terminal includes an output positive terminal and a GND terminal; the full bridge circuit is electrically connected to the input terminal, and the four synchronous rectification circuits are electrically connected to the output terminal.

2. The power conversion apparatus of claim 1, wherein the four synchronous rectification circuits are a first synchronous rectification circuit, a second synchronous rectification circuit, a third synchronous rectification circuit, and a fourth synchronous rectification circuit, respectively; in each synchronous rectification circuit, a second end of the first low-voltage winding and a second end of the second low-voltage winding are electrically connected to the output positive terminal, a first end of the first low-voltage winding is electrically connected to the first lower switch, and a first end of the second low-voltage winding is electrically connected to the second lower switch; and the first lower switch and the second lower switch are both electrically connected to the GND terminal.

3. The power conversion apparatus of claim 2, wherein the two upper switches are a first upper switch and a second upper switch; the two middle switches are a first middle switch and a second middle switch; the first upper switch and the first middle switch are electrically connected to a first node, and the second upper switch and the second middle switch are electrically connected to a second node; the resonant capacitor and the first high-voltage winding and the second high-voltage winding are connected in series between the first node and the second node; a first end of the second high-voltage winding is electrically connected to a second end of the first high-voltage winding; the first upper switch and the second upper switch are both electrically connected to the input positive terminal, and both the first middle switch and the second middle switch are electrically connected to the output positive terminal.

4. The power conversion apparatus of claim 3, wherein the first end of the first high-voltage winding and the first end of the second high-voltage winding, the first end of each of the first low-voltage windings and the second end of each of the second low-voltage windings are with the same polarity.

5. The power conversion apparatus of claim 3, wherein the two magnetic cores are a first magnetic core and a second magnetic core, respectively; each magnetic core comprises a first side column, a middle column, a second side column, an upper magnetic cover and a lower magnetic cover; the first side column, the second side column and the middle column are located between the upper magnetic cover and the lower magnetic cover; the first side column, the middle column, and the second side column are sequentially arranged in the same direction; a first winding channel is between the first side column and the middle column, and a second winding channel is between the second side column and the middle column; each magnetic core comprises an inner side surface and an outer side surface opposite to each other, and the inner side surface of the first magnetic core is adjacent to the inner side surface of the second magnetic core.

6. The power conversion apparatus of claim 5, wherein the first low-voltage winding in each synchronous rectification circuit passes through one winding channel, and the second low-voltage winding in each synchronous rectification circuit passes through another winding channel.

7. The power conversion apparatus of claim 5, wherein the first end of the first high-voltage winding and the second end of the second high-voltage winding are both disposed adjacent to the inner side surface of the magnetic core, and are arranged adjacent to the first winding channels;
wherein from the first end of the first high-voltage winding to the second end of the second high-voltage winding, first the high-voltage winding is wound at least three circles around the middle column of the first magnetic core and the middle column of the second magnetic core in one direction, reaching an intermediate node, then divided into a first winding and a second winding, the first winding is wound one circle around the middle column of the first magnetic core in the same direction to reach the second node, the second winding is wound one circle around the middle column of the second magnetic core to reach the second node;
the first winding and the second winding being electrically connected in parallel between the intermediate node and the second node, and the second node being the second end of the second high-voltage winding.

8. The power conversion apparatus of claim 5, further comprising a substrate, wherein the substrate comprises a top surface and a bottom surface opposite to each other, and the two magnetic cores are respectively assembled with the substrate; the lower switches in the first synchronous rectification circuit are disposed adjacent to the inner side surface of the first magnetic core, the first lower switch of the first synchronous rectification circuit is disposed adjacent to the first winding channel, and the second lower switch of the first synchronous rectification circuit is disposed adjacent to the second winding channel;
wherein the lower switches in the second synchronous rectification circuit are disposed adjacent to the outer side surface of the first magnetic core, the first lower switch of the second synchronous rectification circuit is disposed adjacent to the second winding channel, and the second lower switch of the second synchronous rectification circuit is disposed adjacent to the first winding channel; the lower switches in the third synchronous rectification circuit are disposed adjacent to the inner side surface of the second magnetic core, and the first lower switch of the third synchronous rectification circuit is disposed adjacent to the second winding channel, and the second lower switch of the third synchronous rectification circuit is disposed adjacent to the first winding channel; the lower switches in the fourth synchronous rectification circuit are disposed adjacent to the outer side surface of the second magnetic core, and the first lower switch of the fourth synchronous rectification circuit is disposed adjacent to the first winding channel, and the second lower switch of the fourth synchronous rectification circuit is disposed adjacent to the second winding channel.

9. The power conversion apparatus of claim 8, wherein the first low-voltage winding in the first synchronous rectification circuit passes through the first winding channel of the first magnetic core in a first direction from the first end to the second end, and the second low-voltage winding in the first synchronous rectification circuit passes through the second winding channel of the first magnetic core in the first direction from the first end to the second end;
wherein the first low-voltage winding in the second synchronous rectification circuit passes through the second winding channel of the first magnetic core in a second direction from the first end to the second end, and the second low-voltage winding in the second synchronous rectification circuit passes through the first winding channel of the first magnetic core in the second direction from the first end to the second end; the first low-voltage winding in the third synchronous rectification circuit passes through the second winding channel of the second magnetic core in the second direction from the first end to the second end, and the second low-voltage winding in the third synchronous rectification circuit passes through the first winding channel of the second magnetic core in the second direction from the first end to the second end;
wherein the first low-voltage winding in the fourth synchronous rectification circuit passes through the first winding channel of the second magnetic core in the first direction from the first end to the second end, the second low-voltage winding in the fourth synchronous rectification circuit passes through the second winding channel of the second magnetic core in the first direction from the first end to the second end, and the first direction is opposite to the second direction.

10. The power conversion apparatus of claim 8, further comprising at least three output capacitor groups, wherein the at least three output capacitor groups are respectively arranged on the outer side of the lower switches of the second synchronous rectification circuit, between the lower switches of the first synchronous rectification circuit and the lower switches of the third synchronous rectification circuit, and on the outer side of the lower switches of the fourth synchronous rectification circuit.

11. The power conversion apparatus of claim 8, further comprising at least four groups of output terminals, each group of output terminals being disposed adjacent to the lower switch of a corresponding synchronous rectification circuit.

12. The power conversion apparatus of claim 8, wherein the first lower switch comprises two switches connected in parallel, the second lower switch comprises two switches connected in parallel,
wherein the first lower switch, the second lower switch, and the output capacitor are all arranged on the top surface and the bottom surface of the substrate; two switches connected in parallel in the first lower switch are respectively arranged on the top surface and the bottom surface of the substrate, projections of the two parallel switches on the top surface of the substrate at least partially overlap; two switches in parallel in the second lower switch are respectively provided with the top surface and the bottom surface of the substrate, and projections of the two parallel switches on the top surface of the substrate at least partially overlap;
wherein the projections of the output capacitor arranged on the top surface and the bottom surface of the substrate on the top surface of the substrate at least partially overlap.

13. The power conversion apparatus of claim 5, wherein the two first winding channels are arranged in a penetrating manner in a horizontal direction, and the two second winding channels are arranged in a penetrating manner in a horizontal direction.

14. The power conversion apparatus of claim 5, further comprising a substrate, wherein the substrate comprises a top surface and a bottom surface opposite to each other, and the two magnetic cores are respectively assembled with the substrate; the two upper switches and the two middle switches are disposed adjacent to the first side column, and the two upper switches and the two middle switches are sequentially arranged in the same direction along a sequence of the first middle switch, the first upper switch, the second upper switch, and the second middle switch; the resonant capacitor is disposed adjacent to the upper switch and the middle switch.

15. The power conversion apparatus of claim 14, further comprising an input terminal and an input capacitor, wherein the input terminal and the input capacitor are disposed adjacent to the upper switch and middle switch.

16. The power conversion apparatus of claim 5, further comprising a substrate, the substrate comprising a top surface and a bottom surface opposite to each other, a plurality of holes and a plurality of hole grooves, the holes and the hole grooves both penetrating the top surface and the bottom surface of the substrate, the holes being used for placing the first side column and the middle column of the magnetic core, and the hole grooves being used for placing the second side column of the magnetic core.

17. A power conversion apparatus, comprising:
an input positive terminal, an input negative terminal, an output positive terminal, an output negative terminal, a high-voltage switch, a low-voltage switch, and a magnetic assembly,
wherein the magnetic assembly comprises two magnetic cores, a high-voltage winding and a low-voltage winding; the high-voltage switch is electrically connected to the high-voltage winding, and the low-voltage switch is electrically connected to the low-voltage winding; the two magnetic cores are respectively a first magnetic core and a second magnetic core;
each magnetic core comprise an upper magnetic cover, a lower magnetic cover, a first side column, a middle column, and a second side column; the first side column, the middle column, and the second side column are sequentially arranged in the same direction; the first side column, the middle column, and the second side column are all arranged between the upper magnetic cover and the lower magnetic cover; in the same magnetic core, a first winding channel is between the first side column and the middle column, and a second winding channel is between the second side column and the middle column; the first magnetic core and the second magnetic core are arranged adjacent to each other, the two first winding channels are arranged in a penetrating manner in a horizontal direction, and the two second winding channels are arranged in a penetrating manner in the horizontal direction; the high winding wound the middle columns of the two magnetic cores; the low-voltage winding penetrates the first winding channel or the second winding channel.

18. The power conversion apparatus of claim 17, the high-voltage winding comprises a first high-voltage winding and a second high-voltage winding; a second end of the first high-voltage winding is connected in series with a first end of the second high-voltage winding, and a first end of the first high-voltage winding and a second end of the second high-voltage winding are both located between the two magnetic cores and are arranged adjacent to the first side column;
wherein the winding manner of the high-voltage winding from the first end to the second end is: first, starting from between the two magnetic cores to wind simultaneously around two middle columns in the same direction for N circles and then reach an intermediate node, wherein N is a natural number greater than or equal to 1, and the intermediate node is also located in the middle of the two magnetic cores; then dividing from the intermediate node into a first winding and a second winding, the first winding continues to be wound around the middle column of the first magnetic core in the same direction for one circle and then reaches a second node, the second winding continues to be wound around the middle column of the second magnetic core in the same direction for one circle and then reaches the second node, the first winding and the second winding are connected in parallel between the intermediate node and the second node, and the second node is the second end of the second high-voltage winding.

19. The power conversion apparatus of claim 17, wherein the low-voltage switch is respectively located on two opposite sides of the first magnetic core and two opposite sides of the second magnetic core, a first end of the low-voltage winding is electrically connected to the low-voltage switch, a second end of the low-voltage winding is electrically connected to the output positive terminal, the low-voltage switch is electrically connected to the output negative terminal, and the low-voltage winding comprises a first low-voltage winding and a second low-voltage winding; the first low-voltage winding and the second low-voltage winding pass through the first winding channel and the second winding channel in the same magnetic core, respectively.

20. A system card, comprising:
a system board, a load chip, a socket, a voltage regulator array, and the power conversion apparatus of claim 1,
wherein the system board comprises a top surface and a bottom surface opposite to each other, the load chip is arranged on the top surface of the system board, and the voltage regulator array is arranged on the bottom surface of the system board; projections of the voltage regulator array and the load chip on the system board are at least partially overlapped, the voltage regulator array are electrically connected with the load chip by means of the system board, and the power conversion apparatus is electrically connected to the voltage regulator array; the sockets are disposed on two opposite sides of the voltage regulator array, and the sockets are electrically connected to the load chip.

21. The system card of claim 20, further comprising a module substrate;
wherein the module substrate comprises a top surface and a bottom surface opposite to each other wherein the voltage regulator array and the power conversion apparatus are both disposed on the top surface of the module substrate, and the power conversion apparatuses are disposed on two opposite sides of the voltage regulator array;
the bottom surface of the module substrate is provided with a BGA pad, and the bottom surface of the module substrate is welded to the bottom surface of the system board through the BGA pad.

22. The system card of claim 20, wherein the power conversion apparatus is disposed on the top surface of the system board and disposed adjacent to two opposite sides of the load chip, and a wiring direction between the power conversion apparatus and the voltage regulator array is along X direction; a wiring direction between the load chip and the socket is along the Y direction.

23. The system card of claim 20, further comprising a first output capacitor and a second output capacitor, wherein the first output capacitor is disposed adjacent to the power conversion apparatus, and the first output capacitor is electrically connected to the output terminal of the power conversion apparatus; the second output capacitor is disposed around each voltage regulator in the voltage regulator array, and the second output capacitor is electrically connected to an output terminal of the voltage regulator array.

24. The system card of claim 20, further comprising a module substrate, the module substrate comprises a top surface and a bottom surface opposite to each other; wherein the voltage regulator array is disposed on the top surface of the module substrate, the bottom surface of the module substrate is provided with a BGA pin, and the module substrate is electrically connected to the system board by means of the BGA pin; a second output capacitor is integrated in the module substrate, and the second output capacitor is electrically connected to an output terminal of the voltage regulator array.

25. A manufacturing method for an integrated capacitor substrate, the integrated capacitor substrate comprising a capacitor and a double-sided board, wherein the capacitor is connected with two pads; the manufacturing method comprising:
step 1: embedding the capacitor in the double-sided substrate, and drawing pad pins of the capacitor by means of laser drilling;
step 2: respectively laminating an insulating layer and a layer of copper foil on a top surface and a bottom surface of the double-sided board with the embedded capacitor, thereby forming at least four layers of the substrate;
step 3: for the at least four-layer substrate, a via is provided in a region where the capacitor is not embedded; in a region where the capacitor is embedded, a laser hole is drilled at a position corresponding to the pads lead-out position; the capacitor is disposed adjacent to the via;
step 4: a BGA pin is formed in a position of the via in the at least four-layer substrate and the position of the laser hole.

26. The manufacturing method of claim 25, wherein the capacitor is a silicon capacitor, and a pad of the silicon capacitor is a square pad.

27. A power supply module, comprising:
a circuit substrate, a voltage regulator array and a plurality of power conversion apparatuses,
wherein the circuit substrate comprises a top surface and a bottom surface opposite to each other; the voltage regulator array and the power conversion apparatuses are disposed on the bottom surface of the circuit substrate; the power conversion apparatuses are electronically connected with the voltage regulator array, and supply power to the voltage regulator array; the voltage regulator array supplies power to a load chip; the projections of the load chip and the voltage regulator array on the bottom surface of the circuit substrate are at least partially overlapped; the plurality of the power conversion apparatuses are disposed on the two opposite sides of the voltage regulator array, respectively.

28. The power supply module of claim 27, wherein the circuit substrate is a system board, and the load chip is disposed on a top surface of the system board.

29. The power supply module of claim 27, wherein a BGA pin is disposed on the top surface of the circuit substrate.
